(19) United States
(12) Patent Application Publication
(10) Pub. No.: US 2022/0236441 A1
(43) Pub. Date: Jul. 28, 2022

(54) HIGH-DENSITY INTEGRATED MAGNETIC RECEIVING ANTENNA FOR ELECTROMAGNETIC EXPLORATION

(71) Applicant: HUNAN UNIVERSITY OF SCIENCE AND TECHNOLOGY, Xiangtan (CN)

(72) Inventors: Guohong FU, Xiangtan (CN); Qiyun JIANG, Xiangtan (CN); Songyuan FU, Xiangtan (CN); Hui CHENG, Xiangtan (CN)

(21) Appl. No.: 17/687,243

(22) Filed: Mar. 4, 2022

Related U.S. Application Data
(63) Continuation of application No. PCT/CN2021/084293, filed on Mar. 31, 2021.

(30) Foreign Application Priority Data
Mar. 31, 2020 (CN) 202010240676.3

(51) Int. Cl. G01V 3/10; H01Q 7/00; H05K 1/02; H05K 1/11

(52) U.S. Cl. CPC G01V 3/10; H01Q 7/00; H05K 2201/10151; H05K 1/115; H05K 1/0296

(57) ABSTRACT

A high-density integrated magnetic receiving antenna for electromagnetic exploration, including a multi-layer PCB. A PCB coil of multiple turns are drawn on each conductive layer of the multi-layer PCB, and is continuously wound on each conductive layer of the multi-layer PCB. PCB coils respectively on adjacent conductive layers are connected end to end via a conductive via or a conductive via and a jumper wire such that the PCB coils on each conductive layer of the multi-layer PCB are connected in series to form the high-density integrated magnetic receiving antenna with multiple turns.

### CROSS-REFERENCE TO RELATED APPLICATIONS

This application is a continuation of International Patent Application No. PCT/CN2021/084293, filed on Mar. 31, 2021, which claims the benefit of priority from Chinese Patent Application No. 202010240676.3, filed on Mar. 31, 2020. The content of the aforementioned application, including any intervening amendments thereto, is incorporated herein by reference in its entirety.

### TECHNICAL FIELD

This application relates to electromagnetic exploration, and more particularly to a high-density integrated magnetic receiving antenna for electromagnetic exploration.

### BACKGROUND

Electromagnetic exploration is conducted by time domain electromagnetic method (transient electromagnetic method) or frequency domain electromagnetic method. With respect to the transient electromagnetic method, an ungrounded loop or grounded line source is used to emit a primary pulsed magnetic field into the ground, and during an intermittent period of the primary pulsed magnetic field, a coil or a grounded electrode is used to observe the secondary eddy current field. Moreover, in the transient electromagnetic method, a small wireframe wound with multiple turns of wires with a small diameter is generally used as a magnetic receiving antenna to receive magnetic signals, or a magnetic rod wound with a coil is used to produce a magnetic rod receiving antenna. As for the frequency domain electromagnetic method, an electrical source is commonly used to emit electromagnetic fields, and in the case of difficult grounding operation or difficult construction of electrical sources, a loop coil or a magnetic rod is used to emit magnetic fields. In the frequency domain electromagnetic method, the common frequency range is 10⁻² Hz-10⁴ Hz. To receive magnetic component signals, a coil is wound on a magnetic rod to produce a magnetic receiving antenna, or a multi-turn air-core coil is used as an antenna for the magnetic reception.

The above two electromagnetic methods both involve the measurement of magnetic field signals. In the prior art, a multi-turn coil or a magnetic rod manually wound with copper wires is generally used to receive magnetic field signals. Unfortunately, limited by materials, technologies, and processes, the traditional production of the magnetic receiving coils has many deficiencies, such as large consumption of raw materials, large space occupation, poor consistency of the wound coils, complicated calibration process, and low production efficiency.

### SUMMARY

To overcome the above deficiencies in the prior art, the present disclosure provides a high-density integrated PCB antenna for receiving magnetic field in the electromagnetic exploration, which has high coil density, light weight, excellent durability and good consistency, and does not need manual winding, and thus suitable for batch production.

Technical solutions of the present disclosure are described as follows.

This application provides an integrated magnetic receiving antenna for electromagnetic exploration, comprising:

a multi-layer printed-circuit board (PCB);

wherein a PCB coil of multiple turns is drawn on each conductive layer of the multi-layer PCB, and is continuously wound on each conductive layer of the multi-layer PCB; PCB coils respectively on adjacent conductive layers are connected end to end via a conductive via or a conductive via and a jumper wire such that PCB coils of the multi-layer PCB plate are connected in series to form the integrated magnetic receiving antenna with multiple turns.

In some embodiments, the PCB coils are drawn in square, rectangle, triangle, circle, ellipse, or other polygons. The PCB coils can be drawn as needed to ensure a larger rounded region.

In some embodiments, a middle area of the PCB coils is a through hole to lighten the integrated magnetic receiving antenna.

In some embodiments, a soft magnetic material is arranged in the through hole of the multi-layer PCB to increase the receiving sensitivity.

In some embodiments, two or more multi-layer PCB are laminated; and the PCB coils of the two or more multi-layer PCBs are connected in series to form the integrated magnetic receiving antenna with multiple turns.

In some embodiments, the multi-layer PCB comprises a plurality of multi-layer PCBs; the plurality of multi-layer PCBs are laid out transversely on a horizontal plane; and PCB coils of the plurality of multi-layer PCBs are connected in series to form the magnetic integrated receiving antenna with a larger equivalent receiving region.

In some embodiments, two multi-layer PCBs are arranged orthogonally to receive magnetic field signals of magnetic field components in two orthogonal directions; or three multi-layer PCBs are arranged orthogonally to receive magnetic field signals of magnetic field components in three orthogonal directions.

Compared to the prior art, the present disclosure has the following beneficial effects.

The integrated magnetic receiving antenna provided herein has high density, good consistency, light weight and excellent durability, and does not need manual winding, and thus is suitable for high-efficiency mass production. The integrated antenna provided herein can not only applied to the reception of transient electromagnetic signals, but also to the reception of magnetic field signals in other artificial or natural field source electromagnetic detection signals. Moreover, the integrated magnetic receiving antenna is also suitable for the reception of magnetic field signals in the sky, ground, underground and underwater, and the transmission of low-power signals.

### BRIEF DESCRIPTION OF THE DRAWINGS

FIG. 1 schematically shows a structure of a high-density integrated PCB antenna according to Embodiment 1 of the present disclosure;

FIG. 2 schematically shows a structure of the high-density integrated PCB antenna according to Embodiment 2 of the present disclosure;

FIG. 3 schematically shows a structure of the high-density integrated PCB antenna according to Embodiment 3 of the present disclosure; and

FIG. 4 schematically shows a structure of the high-density integrated PCB antenna according to Embodiment 3 of the present disclosure.

### DETAILED DESCRIPTION OF EMBODIMENTS

The disclosure will be described in detail below with reference to accompanying drawings and embodiments.

### Embodiment 1

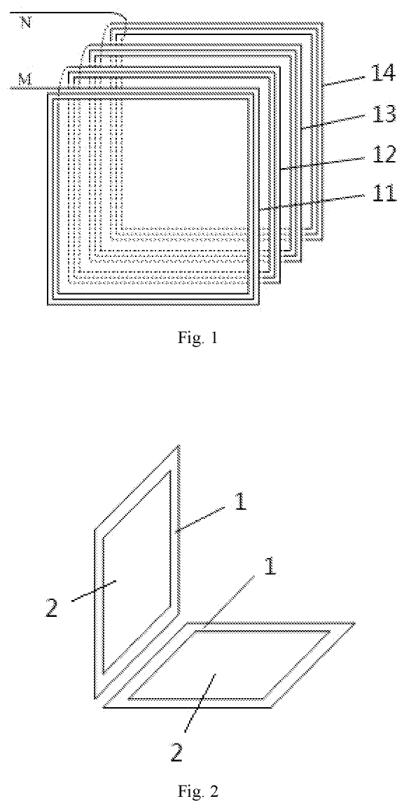

As shown in FIG. 1, a square PCB coil of multiple turns is drawn on each conductive layer of a multi-layer PCB, and is continuously wound on each conductive layer of the multi-layer PCB. PCB coils respectively on adjacent conductive layers are connected end to end via a conductive via and a jumper wire. An outer ring terminal of the square PCB coil is set as a head end, and an inner ring terminal is set as a tail end. Taking a four-layer PCB as an example, the leading end M of the square PCB coil printed on the top layer 11 is configured as a signal output end of the integrated PCB antenna, and the tail end of the top layer 11 is connected to the head end of the square PCB coil printed on the second layer 12 through the conductive via and the jumper wire. The tail end of the second layer 12 is connected to the head end of the square PCB coil printed on the third layer 13 through the conductive via and the jumper wire. The tail end of the third layer 13 is connected to the head end of the square PCB coil printed on the fourth layer 14 through the conductive via and the jumper wire, and the tail end of the fourth layer 14 is connected to the other signal output end N of the PCB integrated antenna through the jumper wire. In the practical application, the PCB integrated coil induces the magnetic field signal to generate an electrical signal, which are output from the M and N ends of the PCB integrated antenna. According to the manufacturing process of PCB, a single multi-layer PCB can be designed with multi-layer PCB coils (currently no more than 20 layers). The printed PCB coils of the multiple conductive layers can be connected through the conductive via and the jumper wire to form a high-density integrated antenna with multiple turns, which is especially suitable as a magnetic signal receiving antenna for the electromagnetic exploration. When the number of turns of the PCB coil on a single multi-layer PCB plate is not enough, two or more multi-layer PCBs can be laminated such that the PCB coils can be connected in series to increase the number of turns of the integrated magnetic receiving antenna.

### Embodiments 2-3

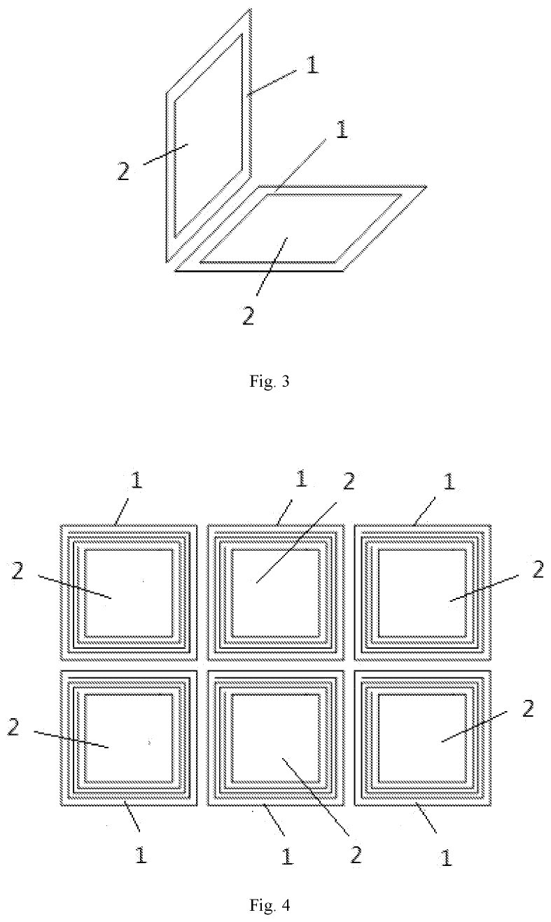

As shown in FIGS. 2-3, “1” represents the multi-layer PCB, and “2” represents the through hole. The PCB coil is square, in which the middle region without wiring is the through hole. In an embodiment illustrated in FIG. 2, two multi-layer PCBs are arranged orthogonally to receive magnetic field signals of magnetic field components in two orthogonal directions. In an embodiment illustrated in FIG. 3, three multi-layer PCBs are arranged orthogonally to receive magnetic field signals of magnetic field components in three orthogonal directions.

### Embodiments 4

As shown in FIG. 4, “1” represents the multi-layer PCB, and “2” represents the through hole. The PCB coil is square, in which the middle region without wiring is the through hole. A plurality of multi-layer PCB plates are laid out transversely on a horizontal plane, and PCB coils of the plurality of multi-layer PCBs are connected in series to form an integrated magnetic receiving antenna with a larger equivalent receiving region.

In addition, in the use of a small-sized transmitting coil to transmit a signal, a soft magnetic material with high permeability may be arranged in the through hole of the multi-layer PCB plate to reduce the size of the antenna and enhance the receiving sensitivity or the strength of the transmitted signal. Thus, the arrangement of a soft magnetic material with high permeability in the PCB coil provided herein for receiving or transmitting magnetic signals also falls within the scope of the present application defined by the appended claims.

What is claimed is:

1. A integrated magnetic receiving antenna for electromagnetic exploration, comprising:
a multi-layer printed-circuit board (PCB);
wherein a PCB coil of multiple turns is drawn on each conductive layer of the multi-layer PCB, and is continuously wound on each conductive layer of the multi-layer PCB; PCB coils respectively on adjacent conductive layers are connected end to end via a conductive via or a conductive via and a jumper wire such that PCB coils of the multi-layer PCB are connected in series to form the integrated magnetic receiving antenna with multiple turns.

2. The integrated magnetic receiving antenna of claim 1, wherein the PCB coils are drawn in square, rectangle, triangle, circle, ellipse, or other polygons.

3. The integrated magnetic receiving antenna of claim 1, wherein a middle area of the PCB coil is a through hole.

4. The integrated magnetic receiving antenna of claim 3, wherein a soft magnetic material is arranged in the through hole of the multi-layer PCB.

5. The integrated magnetic receiving antenna of claim 1, wherein two or more multi-layer PCBs are laminated, and the PCB coils of the two or more multi-layer PCBs are connected in series to form the integrated magnetic receiving antenna with multiple turns.

6. The integrated magnetic receiving antenna of claim 1, wherein the multi-layer PCB comprises a plurality of multi-layer PCBs; the plurality of multi-layer PCBs are laid out transversely on a horizontal plane; and PCB coils of the plurality of multi-layer PCBs are connected in series.

7. The integrated magnetic receiving antenna of claim 1, wherein two multi-layer PCBs are arranged orthogonally to receive magnetic field signals of magnetic field components in two orthogonal directions; or three multi-layer PCBs are arranged orthogonally to receive magnetic field signals of magnetic field components in three orthogonal directions.
